(19) United States
(12) Patent Application Publication
(10) Pub. No.: US 2009/0173984 A1
(43) Pub. Date: Jul. 9, 2009

(54) INTEGRATED CIRCUIT AND METHOD OF MANUFACTURING AN INTEGRATED CIRCUIT

(75) Inventor: Peng-Fei Wang, Dresden (DE)

Correspondence Address: COATS & BENNETT/QIMONDA, 1400 CRESCENT GREEN, SUITE 300, CARY, NC, 27518, US

(73) Assignee: QIMONDA AG, Munchen (DE)

(21) Appl. No.: 11/970,640

(22) Filed: Jan. 8, 2008

(51) Int. Cl. H01L 29/788; H01L 21/336

(52) U.S. Cl. 257/315; 438/257; 257/E29.264; 257/E21.421

(57) ABSTRACT

The present invention provides an integrated circuit with a floating body transistor comprising two source/drain regions and a floating body region arranged between the two source/drain regions comprising: a back gate electrode separated from the floating body by a first dielectric layer; a control gate electrode, separated from the floating body by a second dielectric layer and overlying the back gate electrode; and a third dielectric layer arranged between the back gate electrode and the control gate electrode. The present invention provides also a method of manufacturing an integrated circuit and a method of operating an integrated circuit.

### BACKGROUND OF THE INVENTION

1. Field of the Invention

The present invention relates to an integrated circuit and a method of manufacturing an integrated circuit. The present invention relates further to a method of operating an integrated circuit.

2. Description of the Related Art

Integrated semiconductor circuits often comprise a plurality of DRAM (dynamic random access memory) cells, each DRAM cell comprising one transistor and one capacitor. To increase the density of the DRAM cells on such an integrated semiconductor circuit, it is necessary to decrease the size of each single DRAM cell.

However, many problems arise when the size of a DRAM cell is below 100 nm, especially for the trench-DRAM technology. It is therefore a challenging task to provide a capacitor-less DRAM cell for an integrated semiconductor circuit.

Floating body cell (FBC) memory on SOI (silicon on isolator) has recently been proposed to overcome the scaling challenges of the 1 transistor-1 capacitor DRAM. The most attractive features of the FBC memory are a relative small cell size and the absence of the storage capacitor. Nevertheless, FBC memory devices requiring SOI increase the production costs for an integrated semiconductor circuit comprising these conventional floating body cells. Also, properties of the conventional floating body cells can differ significantly between cells of the same integrated circuit or between integrated circuits of the same type.

### SUMMARY OF THE INVENTION

Various aspects of the invention are listed in Claims 1, 13, 17 and 19.

Further aspects are listed in the respective dependent claims.

Embodiments of the present invention are illustrated in the drawings and are explained in more detail in the description below.

### DESCRIPTION OF THE DRAWINGS

FIGS. 1A to H show schematic layouts for illustrating an embodiment of the method of fabricating an integrated semiconductor circuit; namely a) as a cross section of an array perpendicular to a wordline to be formed; b) as a cross section of said array parallel to the wordline to be formed; c) as a cross section of a support parallel of the wordline to be formed; and d) as a cross section of said support perpendicular to the wordline to be formed; and

FIG. 2 shows a three-dimensional structure of a first embodiment of a floating body region FB;

FIG. 3 shows a schematic layout for illustrating the working mechanism of a floating body cell of the corresponding integrated semiconductor circuit;

FIG. 4 shows a flowchart for illustrating a method of operating the integrated circuit;

FIGS. 5A and 5B show a plan view of a semiconductor substrate for illustrating a first embodiment of the integrated circuit;

FIGS. 6A to 6C show plan views of a semiconductor substrate for illustrating a second embodiment of the integrated circuit;

FIGS. 7A to 7C show schematic layouts for illustrating a second embodiment of the method of fabrication an integrated circuit; and

FIG. 8 shows a three-dimensional structure of a second embodiment of a floating body region FB.

### DETAILED DESCRIPTION

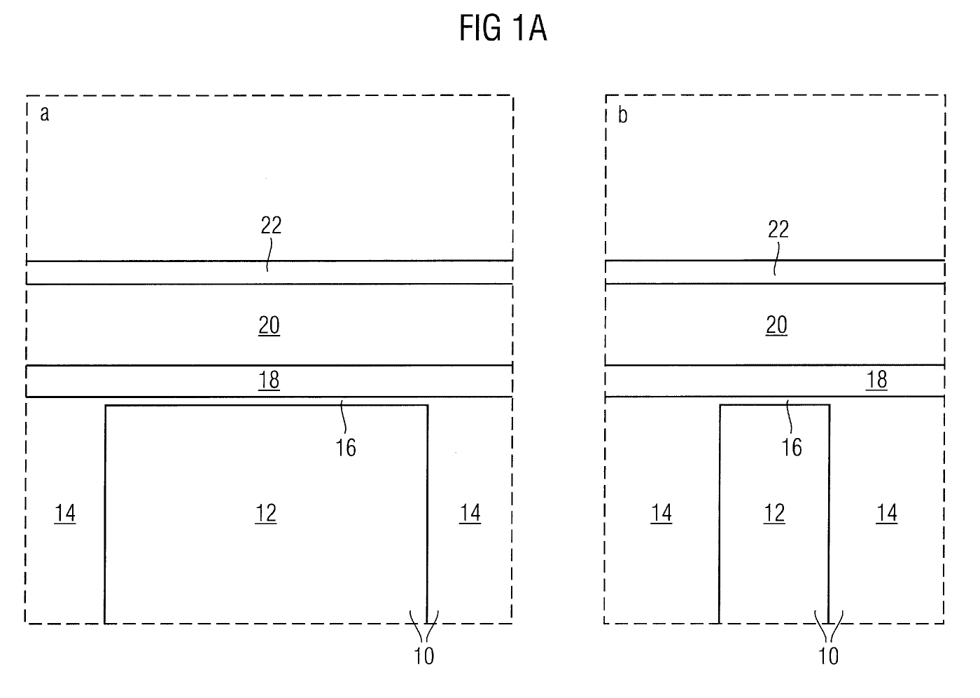

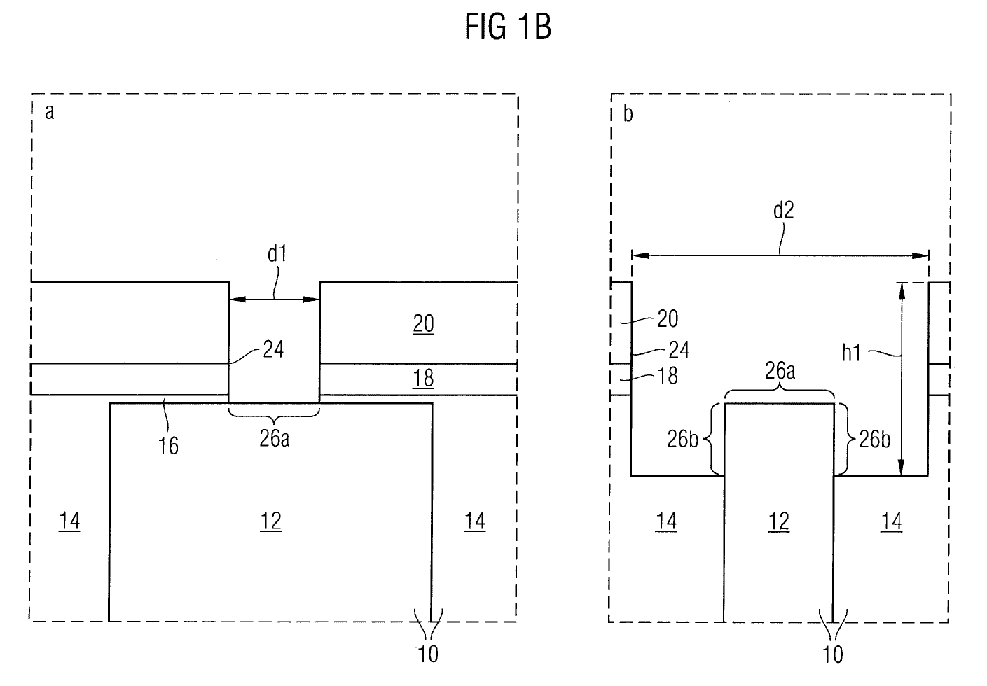

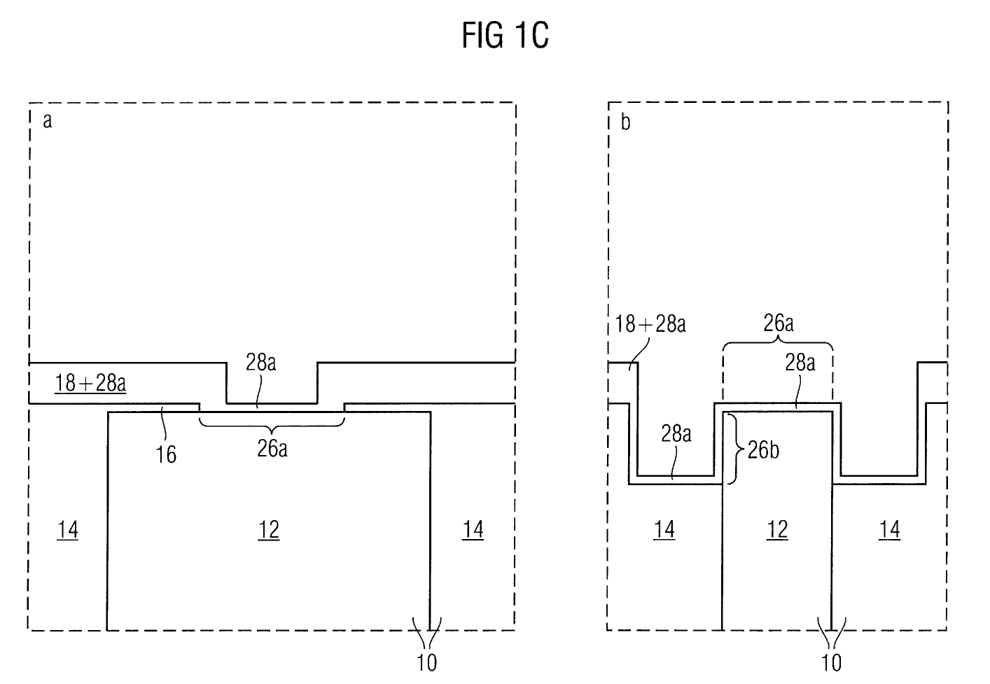

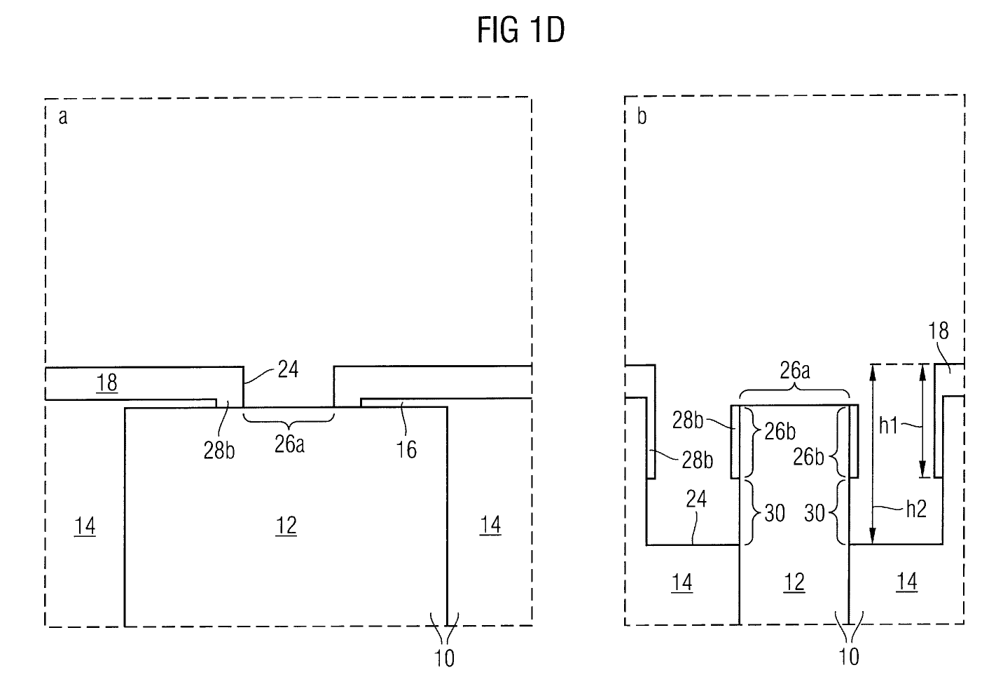

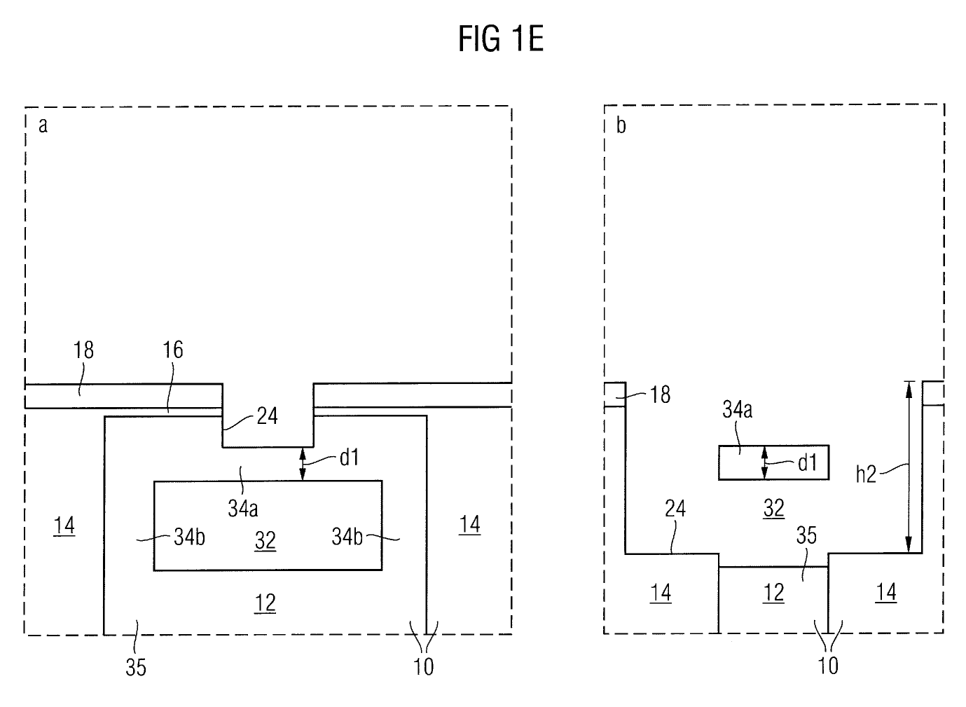

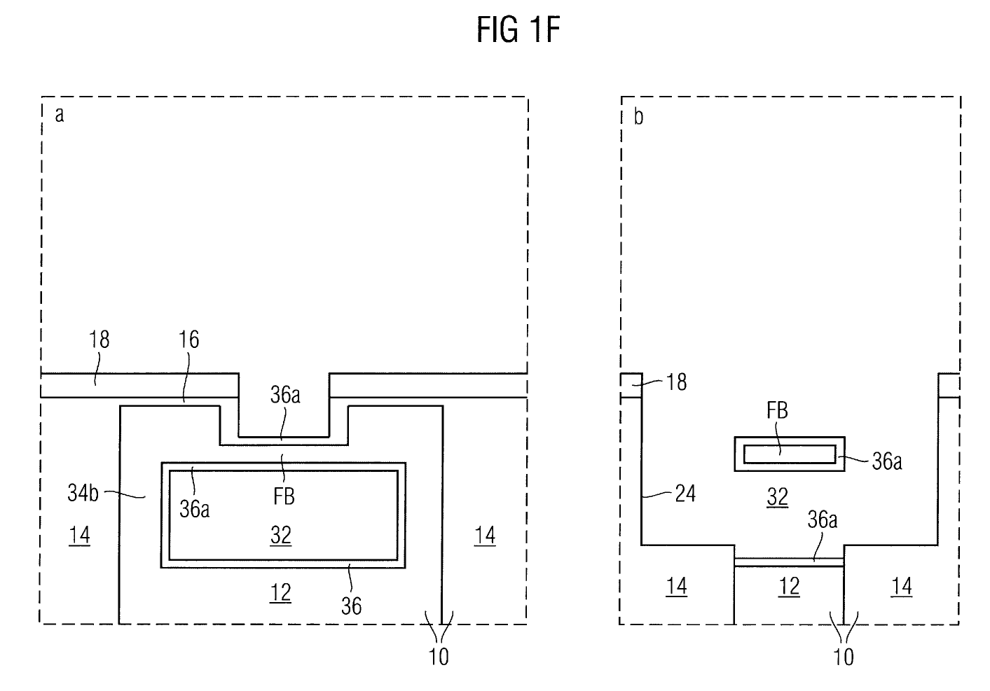

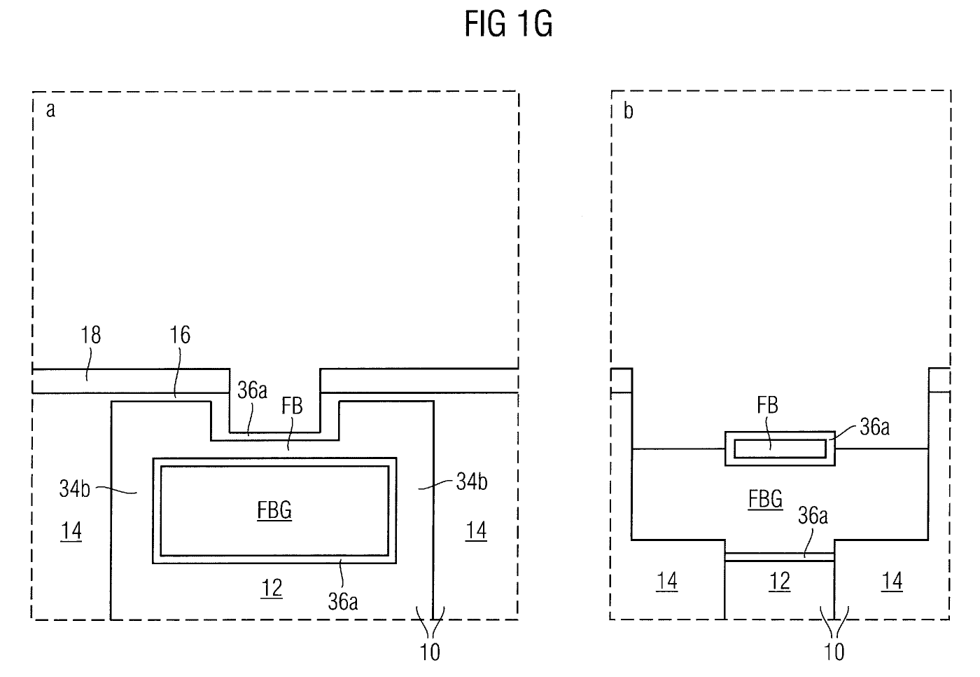

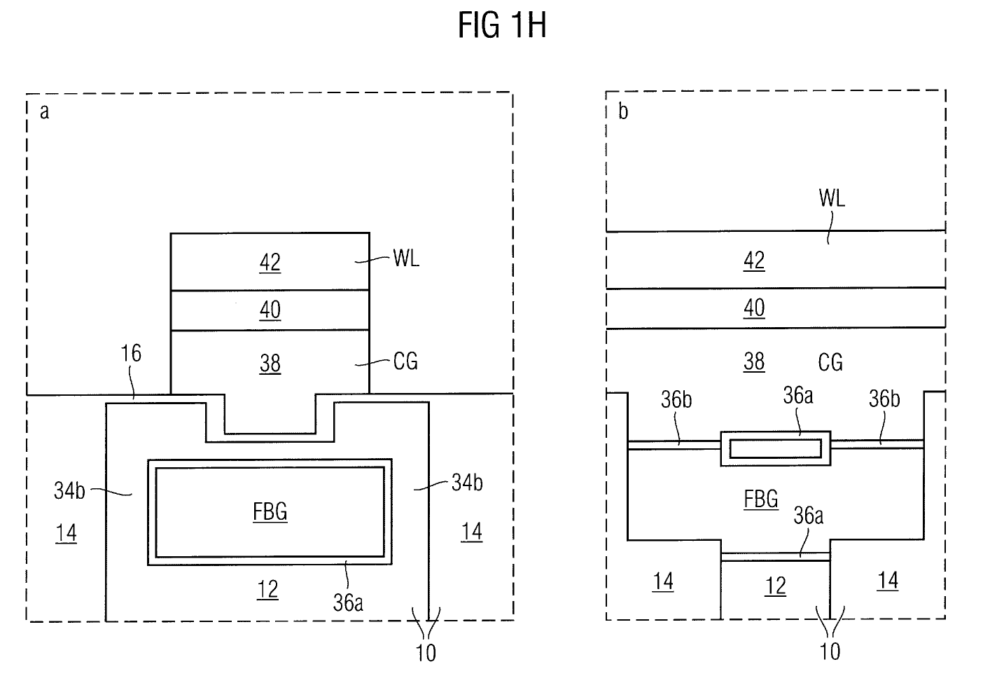

FIGS. 1A to 1H show schematic layouts for illustrating a first embodiment of the method of fabricating an integrated circuit; namely a) as a cross section of an array perpendicular to a wordline to be formed; and b) as a cross section of said array parallel to the wordline to be formed.

In a first process step of the method, a semiconductor substrate 10 is provided, which may comprise silicon. Then, a plurality of parallel active area lines 12 may be formed on said semiconductor substrate 10 by etching isolation trenches 14 into the semiconductor substrate 10. The isolation trenches 14 separate the active area lines 12 from each other. The isolation trenches 14 are then filled with an insulating material. The insulating material may comprise an oxide, silicon oxide for example.

In a following process step, a thin insulation layer 16 may be formed on the surface of the semiconductor substrate 10. The layer thickness of the insulation layer 16 may be in a range between 2 nm to 10 nm. For instance, said insulation layer 16 may be an oxide layer formed by a thermal oxidation step.

However, the present invention is not restricted to the use of an oxide for the filling of the isolation trenches 14 and the insulation layer 16. Various other insulating materials may be deposited on the semiconductor substrate 10 to fill the isolation trenches 14 and/or to form the insulation layer 16.

Then, at least one ion implantation step may be carried out to deposit an ion doping within the semiconductor substrate 10. Thus, well implants and array source/drain implants may be provided within the semiconductor substrate 10. (An example of the function of the transistors is given with regard to FIG. 3.) Furthermore, no implant is shown in FIGS. 1A to H.

In a subsequent process step, a protection layer 18 is deposited on the surface of the semiconductor substrate 10. Said protection layer 18 may cover the filled isolation trenches 14 and the insulation layer 16 completely. The protection layer 18 may comprise silicon nitride, for instance.

Then, a mask 20, for instance a carbon hard mask, is deposited on the surface of the protection layer 18. A capping layer 22 may be deposited on the surface of the mask 20, for instance comprising SiON. The result is shown in FIG. 1A.

The present invention is not restricted to a certain layer thickness of the layers 18, 20 and 22.

In a following process step, the mask 20 and the capping layer 22 are structured. Method to structure the mask 20 and the capping layer 22 are well known and therefore not explained in more details here. Then, the capping layer 22 is removed.

In a following process step, trenches 24 are etched through the protection layer 18. These trenches 24 have a first diameter d1 which is parallel to the active area lines 12 and a second diameter d2 which is perpendicular to the active area lines 12. The first diameter d1 may be smaller than the length of the segments of the active area lines 12 and the second diameter d2 may be larger than the width of the active area lines 12, as it is shown in FIG. 1B.

However, as will be explained in more details below, the diameters d1 and d2 are not restricted to any ranges for the present invention.

Afterwards, another etch step may be performed to increase the depth of the trenches 24 to a first maximal depth h1. The trenches 24 may extend into the isolation trenches 14. For instance, the first maximal depth h1 may be in a range between 50 nm to 200 nm.

The etch steps performed so far may be anisotropic etch steps, for instance reactive ion etch (RIE) steps. For these etch steps an etching material may be chosen that does hardly attack the active area lines 12. Thus, upper regions 26a and 26b of said active area lines 12 may be exposed, as can be seen from FIG. 1B. These exposed upper regions 26a and 26b may comprise stripes 26a of the upper surface of the active area lines 12 and upper regions 26b of the sidewalls of the active area lines 12.

In next process step, which is shown in FIG. 1C, the mask 20 is removed. Then, a thin spacer layer 28a, for instance comprising silicon nitride, is deposited on the surface of the semiconductor substrate 10. Said spacer layer 28a may have a layer thickness between 2 and 10 nm. The spacer layer 28a may cover the sidewalls and the bottoms of the trenches 24 completely. It may also cover the upper regions 26a and 26b of the active area lines 12.

Then, as can be seen from FIG. 1D, an etching step, for example a RIE step, is performed in a direction perpendicular to the surface of the semiconductor substrate 10. Thus, the spacer layer 28a may be removed from all surfaces which are parallel to the surface of the semiconductor substrate 10. Thus, spacers 28b are formed which cover surfaces which are perpendicular to the surface of the semiconductor substrate 10. Therefore, the sidewalls of the trenches 24 and the upper regions 26b of the sidewalls of the active area lines 12 are covered by the spacers 28b. The bottoms of the trenches 24 and the stripes 26a of the upper surface of the active area lines 12 are exposed.

Subsequently, the maximal depth of the trenches 24 is increased to a second maximal depth h2. This may be done by a wet etch step, for instance. The difference between the first maximal depth h1 and the second maximal depth h2 of the trenches 24 may be in a range between 20 nm to 100 nm. Thus, middle regions 30 of the sidewalls of the active area lines 12 are exposed. These middle regions 30 are located below the upper regions 26b of the sidewalls of the active area lines 12.

The wet etch step may be performed with an etching material which does hardly attack the material of the spacers 28b. In this case, the spacers 28b still cover the upper regions 26b of the sidewalls of the active areas lines 12 after the wet etch step.

In a following process step, which is shown in FIG. 1E, an isotropic etch step is carried out to etch the exposed stripes 26a of the upper surface 26a and the middle regions 30 of the sidewalls of the active area lines 12. This isotropic etch step may be performed with an etching material which does hardly attack the insulating materials of the isolation trenches 14 or the spacers 28b. Thus, the upper regions 26b of the sidewalls of the active area lines 12 are protected during this isotropic etch step.

During the isotropic etch step, semicircle-like or bridge-like structures may be etched into the active area lines 12. The isotropic etch step may be stopped after the formation of tunnel-like interspaces 32 within the active area lines 12.

As can be seen from FIG. 1Ea, the newly formed semicircle-like or bridge-like structures may comprise overhead components which may be fin-like active area segments 34a. In this case, the fin-like active area segments 34a provide the material for the later to be formed floating body regions. The thickness d1 of these fin-like active area segments 34a may be within a range from 10 nm to 50 nm. These fin-like active area segments 34a may still be connected to the main bodies 35 of the active area lines 12 by stilts 34b.

After said isotropic etch step, another etch step may be carried out to remove the spacers 28b. This etch step may be performed with an etching material which also attacks the protection layer 18. Thus, the protection layer 18 is depleted. The result is shown in FIG. 1E. In case that the spacers 28b and the protection layer 18 comprise silicon nitride, the etch step may be a silicon-nitride-strip.

Then, as can be seen in FIG. 1F, thin dielectric layers 36a are formed, which cover the exposed surfaces of the fin-like active area segments 34a, the stilts 34b and of the main bodies 35 of the active area lines 12. The thin dielectric layer 36a may be an oxide layer formed by a thermal oxidation step. Thus, floating body regions FB are formed of the former fin-like active area segments 34a. These floating body regions FB are still connected to the main bodies 35 by the stilts 34b.

In the process step shown in FIG. 1G, the through-holes 32 are filled with a material, for example polysilicon, to form floating back gate electrodes FBG. Each of said floating back gate electrodes FBG is isolated from the adjacent floating body region FB and from the adjacent active area line 12 by the dielectric layer 36a. In an additional polishing step, the upper level of the floating back gate electrodes FBG may be recessed to a level at the middle of the floating body region FB.

In a subsequent process step, an oxide strip may be carried out. Additionally, the protection layer 18 may be removed in another etch step, for instance in a wet etch step.

Afterwards, another thermal oxidation step may be carried out to form gate dielectric layers 36b which cover the exposed surface of the floating back gate electrode FBG completely.

Then, a layer 38 of material for control-gate electrodes is deposited on the surface of the semiconductor substrate 10 to form control-gate electrodes CG. Said layer 38 of material for control-gate electrodes may comprise polysilicone. Finally, a first top layer 40 and a second top layer 42 may be deposited on the layer 38 of material for control-gate electrodes. The first top layer 40 may comprise tungsten nitride, while the second top layer 42 may comprise tungsten. In this case, the first top layer 40 is a barrier to prevent the tungsten of the second top layer 42 from diffusing into the layer 38. However, the present invention is not limited to the materials tungsten nitride and tungsten for the top layers 40 and 42 to form a wordline WL.

The process steps performed to structure wordlines WL are well known. Therefore, an explanation of these process steps is not given here.

As shown in FIG. 1H, each floating body cell formed by the process steps described above comprises a floating back gate electrode FBG, a floating body region FB and a control gate electrode CG.

The floating body region FB is arranged between the floating back gate electrode FBG and the control gate electrode CG. As can be seen from FIG. 1H, the floating back gate electrode FBG is surrounded on two sides, which are perpendicular to the wordline WL, by the floating body region FB and the adjacent active area line 12. Thus, it is possible to increase the interaction of the floating body region FB and the floating back gate electrode FBG, as will be described below.

The floating back gate electrode FBG, the floating body region FB and the control gate electrode CG are separated from each other by the thin dielectric layers 36a and 36b. These thin dielectric layers 36a and 36b may have a layer thickness less than 10 nm. Thus, it is possible for electrons to tunnel from the active area lines 12 into the floating back gate electrode FBG. Additionally, a hot channel electron interaction HCE can occur between the floating body region FB and the floating back gate electrode FBG. These interactions between the components of the inventive floating body cell are described in more details below.

The floating body memory cell may be a combination of a floating body cell and a floating gate cell. The floating back gate electrode FBG can be charged with a negative voltage. Thus, the floating back gate electrode FBG displaces a conventional capacitor of a 1T-1C-DRAM. Therefore, the inventive floating body cell may be called a capacitor-less DRAM cell. It is possible to fabricate said floating body cell with a cell size below 90 nm. Thus, the density of memory cells on a wafer can be increased.

In case that a floating body cell has no back gate, a partially depleted SOI (silicon on isolator) is needed to store charges in the floating body/channel region. However, due to the partially depleted SOI, a leakage current may occur. This leakage current may result in a relative low retention time.

No SOI wafer is necessary to build the inventive floating body cell. Thus, the problem of a leakage current is not relevant for the inventive floating body cell.

Those floating body cells that have a common back gate do not need a SOI. However, these floating body cells may have a significant fluctuation in view of the charge stored within the different floating body cells. In this case, a random cell adjustment is hardly possible.

The floating body cell according to an aspect of the invention may have a relative small irregularity in regard of the charge stored on the floating back gate electrodes FBG. Thus, it may be possible to perform Vt adjustments by programming the floating back gate electrode FBG.

Moreover, this floating body cell may be fabricated on bulk silicon substrates to reduce the wafer costs.

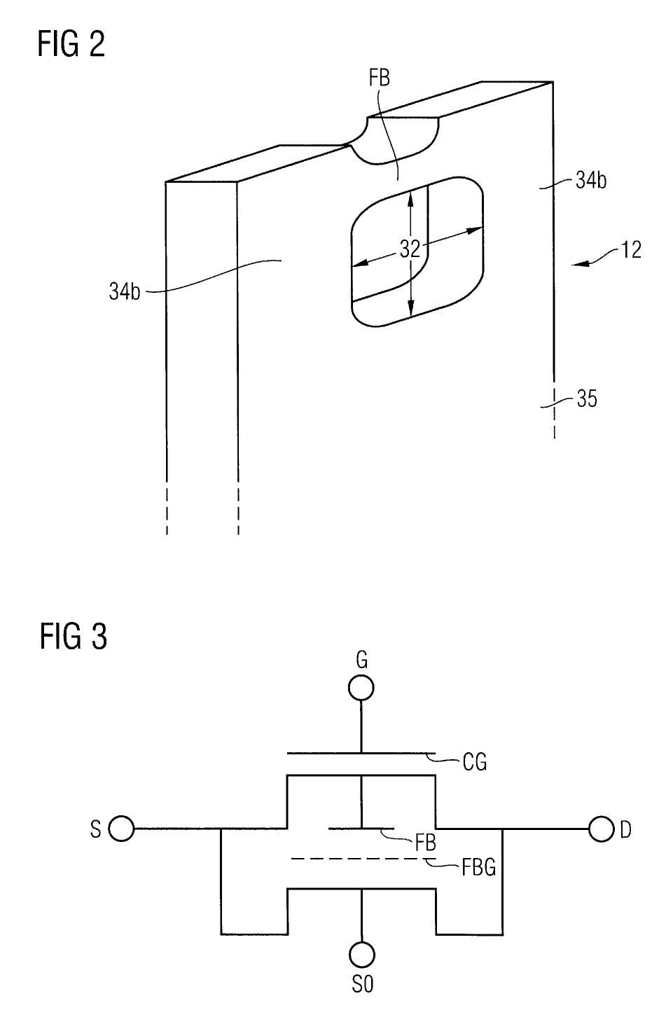

FIG. 2 shows a three-dimensional structure of a first embodiment of a floating body region FB. FIG. 2 corresponds to FIG. 1E.

The floating body region FB is separated from the main body 35 of the active area line 12 by a tunnel-like through-hole 32. Said through-hole 32 is etched into the active area line 12 by the method explained above in regard of FIGS. 1D and 1E. The stilts 34b which are formed on both sides of the through-hole 32 connect the floating body region FB to the main body 35 of the active area line 12. Thus, the two stilts 34b can provide an increased stability for the floating body region FB formed of the material of an active area line 12.

FIG. 2 does not show the thin dielectric layers formed on the uncovered surface of the active area line 12 or the floating back gate electrode FBG, which may be formed by some further steps of the method explained above. Also, the isolation trenches which separate the active area line 12 from the adjacent active area lines 12 are also not shown in FIG. 2.

FIG. 3 shows a schematic layout for illustrating the working mechanism of a floating body cell of the corresponding integrated circuit.

Both transistors share a source S, a drain D and a gate G. Between the lower transistor and the upper transistor a floating back gate electrode FBG is arranged. Beneath the floating back gate electrode FBG, the substrate SO is located. A floating body region FB is formed above the floating back gate electrode FBG. On top of the floating body region FB, a control gate electrode CG is provides. Said control gate electrode CG is connected to the gate G. The substrate S0, the floating back gate electrode FBG and the floating body region FB are separated from each other by (not shown) tunnel oxide layers. The tunnel oxide layers, the floating body region FB, the floating back gate electrode FBG and the control gate electrode CG can be formed according to the method described above in regard of FIGS. 1A to 1H.

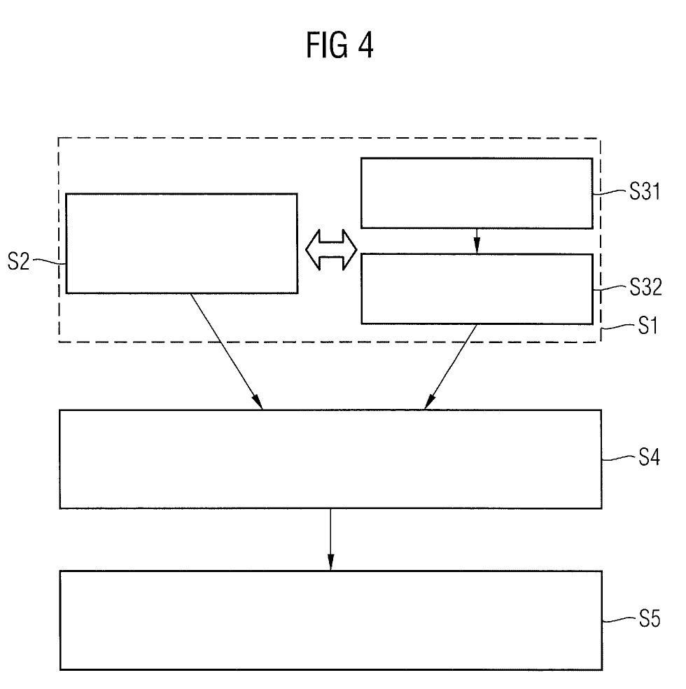

FIG. 4 shows a flowchart for illustrating an embodiment of the method of operating the integrated circuit. Said method may be performed to program a floating body transistor comprising a floating body region arranged between a back gate and a control gate, for instance the floating body cell of FIG. 3.

In a first step S1, an electrical signal with a predetermined signal parameter is applied to the floating body transistor. Here, two different method of applying an electrical signal to the floating body transistor are described. Both methods may be performed to program the floating body cell described above.

To perform the first method, the substrate is connected with a negative voltage while the gate is connected to a positive voltage in a first step S2. For instance, these voltages have the values of −3V and 3V. Now, electrons can tunnel through the tunnel oxide layer between the substrate and the floating back gate electrode. Thus, the floating back gate electrode is loaded with a negative charge and the potential of the floating back gate electrode is modified (step S4).

However, this way of programming the floating back gate electrode takes a relative long time because of the relative low voltage setting and the long tunnel time.

To perform the second method, the same voltages, for example −3V and 3V, may be impressed on the substrate and the gate (step 31). Also, voltages are impressed on the source and the drain in another step S32. Examples for these voltages are the values 0V for the source and 1V for the drain. Because the gates of the upper and the lower transistors are open, there occurs a current from the source to the drain.

Thus, a hot channel electron injection is possible to store an additional charge on the floating back gate electrode and to modify the potential of the floating back gate electrode (step S4). This hot channel electron injection HCE does not inhibit the tunneling of electrons through the tunnel oxide layer from the substrate to the floating back gate electrode. Therefore, the programming time is reduced significantly. The hot channel electron injection also reduces the fluctuations of the charge stored on the floating back gate electrode. Thus, a random Vt adjustment of the programming of the floating back gate electrode is possible.

In a further step S5, the potential of the floating back gate electrode is investigated to determine the current state of the corresponding memory cell.

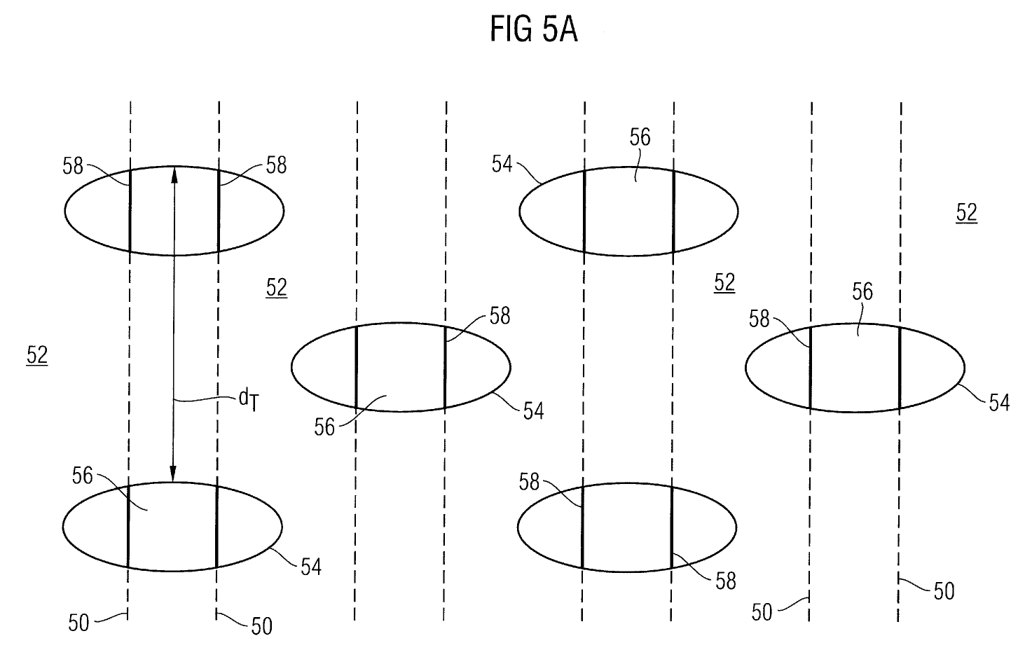

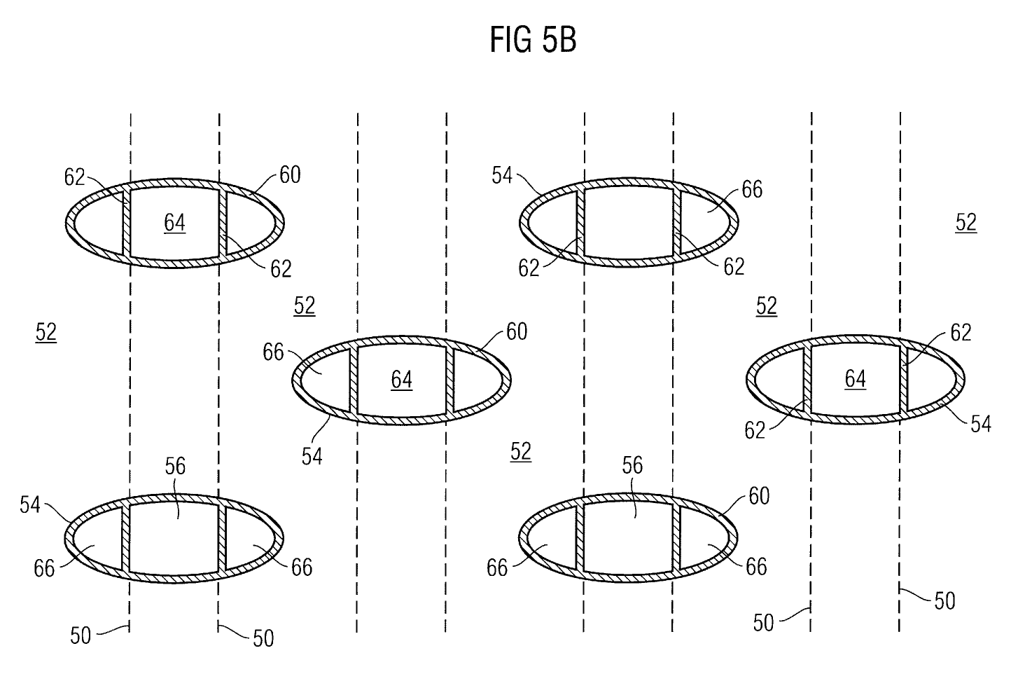

FIGS. 5A and 5B show a plan view of a semiconductor substrate for illustrating a first embodiment of the integrated circuit.

On the surface of the semiconductor substrate a plurality of parallel active area lines is formed. The broken lines 50 of FIG. 5A represent the positions of these active area lines. The active area lines are separated from each other by (not shown) isolation trenches which are etched into the surface of the semiconductor substrate and which are filled with an insulating material, for instance silicone oxide. Then, a thin isolation layer 52 is deposited on the surface of the semiconductor substrate. Thus, the active area lines are covered by the thin isolation layer 52.

According to the method explained above, a plurality of trenches 54 is etches through the isolation layer 52. These trenches 54 have an elliptic base area. The trenches 54 are arranged on the surface of the semiconductor substrate so that each trench 54 is centered around a segment 56 of an active area line. The distance between two adjacent trenches 54 of the same active area line is d_{T}. The positions of the trenches 54 of each active area line are shifted in regard of the positions of the trenches 54 of the adjacent active area line in a direction parallel to the active area lines. For instance, the shifting distance in the direction parallel to the active area lines may be a half of the distance d_{T}. Thus, a relative high number of floating body cells may later be formed, even though an unwanted interaction between the components of adjacent floating body cells is insignificant low.

The trenches 54 extend into the isolation trenches formed between the active area lines. The (not shown) depth of the trenches 54 is large enough to uncover upper side walls 58 of the uncovered segments 56, as has been explained above in regard to FIG. 1B.

FIG. 5B shows a plan view of the semiconductor substrate after the formation of spacers 60 and 62 within the trenches 54. The spacers 60 cover the inner walls of the trenches 54. The upper side walls of the segments 56 of the active are lines are covered by the spacers 62. The spacers 60 and 62 may be formed from the same material according to the method explained above.

The surfaces 64 of the segments 56 of the active are lines are not covered by the spacers 60 or 62. The bottoms of the trenches 54 next to the segments 56 are also exposed of the material of the spacers 60 and 62.

The further steps of the method for forming floating body regions and floating back gate electrodes within the segments 56 are explained above, and are therefore not repeated here.

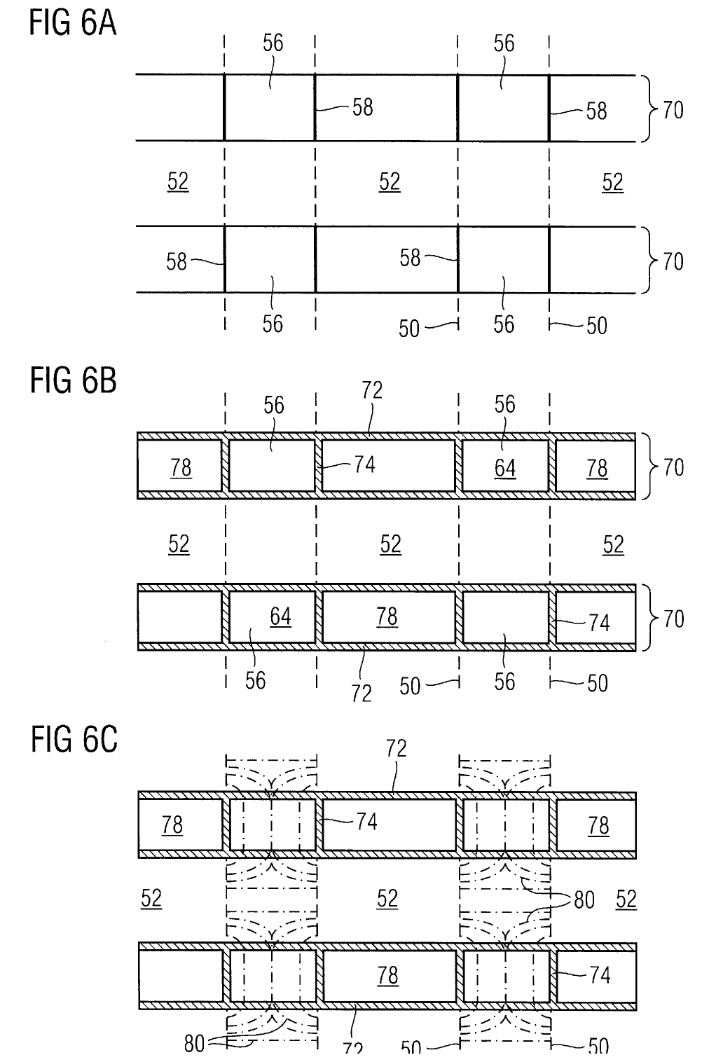

FIGS. 6A to 6C show plan views of a semiconductor substrate for illustrating a second embodiment of the integrated circuit.

In FIG. 6A, the broken lines 50 represent the positions of the active area lines. The active area lines are separated from each other by (not shown) isolation trenches and are covered by a thin isolation layer 52.

According to the method explained above, long trenches 70 are etched into the isolation layer 52. These trenches 70 may run perpendicular to the active are lines. Each trench 70 crosses the plurality of active area lines to uncover segments 56 with upper side walls 58, as has been explained above.

FIG. 6B shows the plan view of the semiconductor substrate after the formation of spacers 72 and 74. The spacers 72 cover the inner side walls of the trenches 70 and the spacers 74 cover the upper side walls of the segments 56. The spacers 72 and 74 may be formed according to the method explained above.

The surfaces 64 of the segments 56 and the bottoms 78 of the trenches 70 are not covered by the spacers 72 and 74. Thus, it is possible to increase the depth of the trenches 70 in a further etch step.

FIG. 6C shows the plan view of the semiconductor substrate during a following isotropic etch step. This isotropic etch step etches Si selectively to the material of the isolation trenches and the spacers 72 and 74. In this case, mainly the regions below the spacers 74 of the segments 56 may be attacked by the etching material. The exposed surfaces of the segments 56 may also be etched.

The etching direction runs isotropically from the bottoms 78 into the unprotected regions of the segments 56 to the middle of the segments 56. Thus, it is possible to form floating gate regions which are completely separated from the main bodies of the active area lines.

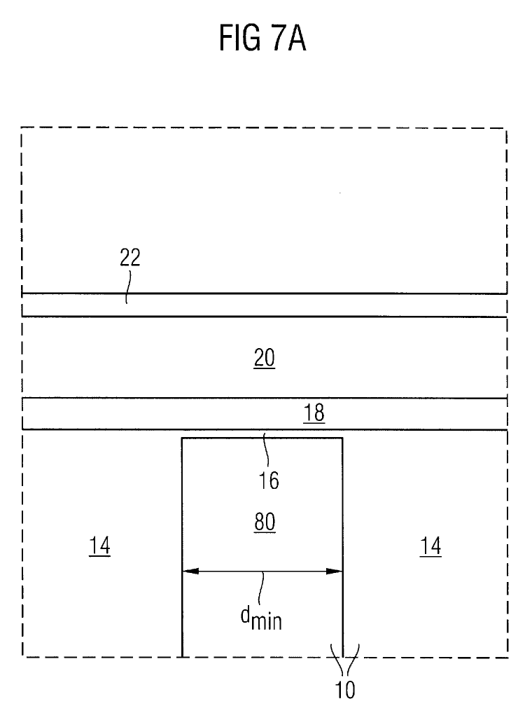

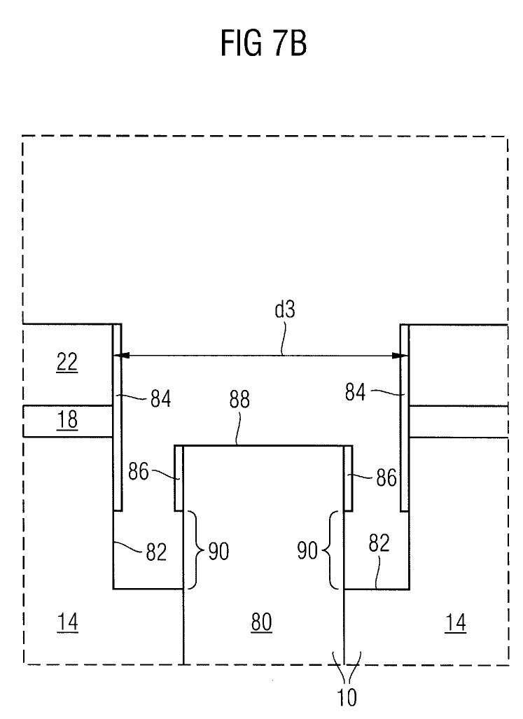

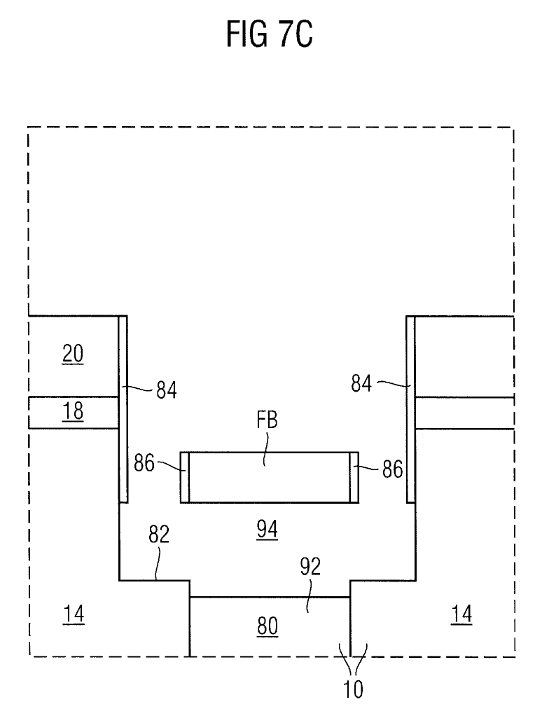

FIGS. 7A to 7C show schematic layouts for illustrating a second embodiment of the method of fabrication an integrated circuit.

The cross section of FIG. 7A corresponds to FIG. 1Aa. It shows a semiconductor substrate 10 with an active area line 80 between two isolation trenches 14. The active area line 80 is covered by a thin isolation layer 16. On the isolation layer 16, a protective layer 18, a mask 20 and a capping layer 22 are deposited. The components 14 to 22 may be the same as those described already in regard of FIG. 1A.

In opposite to the active area line shown in FIG. 1A, the active area line 80 may have a smaller diameter dₘᵢₙ. However, the method explained here is not restricted to a special range for the diameter dₘᵢₙ of the active area line 80.

FIG. 7B shows the cross section through the semiconductor substrate 10 after the etching of a trench 82 and the formation of spacers 84 and 86. The trench 82 and the spacers 84 and 86 may be formed according to the method explained above.

However, the diameter d₃ of the trench 82 perpendicular to the direction of the active are line 80 is larger than the diameter dₘᵢₙ of the active are line. Thus, the surface 88 of the active are line 80 is completely uncovered.

The spacers 84 and 86 do not extend to the bottom of the trench 82. Thus, the side walls of the active area line 80 have uncovered middle-regions 92.

FIG. 7C shows the cross section after an etch step to form a floating body region FB. The etch step may be performed with a material which mainly attacks the uncovered middle-regions 92 of the side walls of the active area line 80.

Said etch step may be stopped just when exposed middle-regions 92 of the active line 80 are completely removed. In this case, as can be seen from FIG. 7C, the floating body region FB is completely separated from the main body 92 of the active area line 80. This is no stilt between the main body 92 and the floating body region FB.

The inter-space 94 between the floating body region FB and the main body 92 may be large enough to form a floating back gate electrode therein. As the floating back gate electrode may be formed according to the method explained above, the further steps are not explained in more details here.

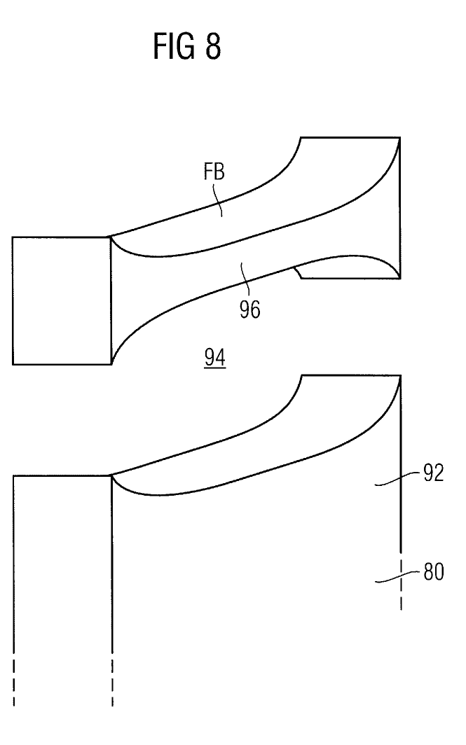

FIG. 8 shows a three-dimensional structure of a second embodiment of a floating body region FB.

The floating body region FB of FIG. 8 may be formed according to the method explained in regard of FIGS. 7A to 7C. The floating body region FB is not linked to the main body 92 of the active area line 80. The through-hole 94 isolates the floating body region FB completely of the main body 92.

However, the floating body region FB may still be in contact with the (not shown) side walls of the trench at the contact areas 96. Thus, the stability of the floating body region FB may be secured, even though there is no connecting element between the floating body region FB and the main body 92.

1. An integrated circuit with a floating body transistor comprising two source/drain regions and a floating body region arranged between the two source/drain regions comprising:
a back gate electrode separated from the floating body by a first dielectric layer;
a control gate electrode, separated from the floating body by a second dielectric layer and overlying the back gate electrode; and
a third dielectric layer arranged between the back gate electrode and the control gate electrode.

2. The integrated circuit according to claim 1, wherein the back gate electrode forms a floating electrode.

3. The integrated circuit according to claim 1, wherein at least one of the dielectric layers comprises silicon oxide.

4. The integrated circuit according to claim 1, wherein the back gate electrode comprises polysilicon.

5. The integrated circuit according to claim 1, wherein the floating body region is surrounded on four sides by either the control gate electrode, the back gate electrode, or the third dielectric layer.

6. The integrated circuit according to claim 1, wherein the back gate electrode and at least a portion of the control gate are arranged in a trench.

7. The integrated circuit according to claim 1, further comprising:
at least a second floating body transistor comprising a second back gate electrode, wherein the first and the second back gate electrodes of the first and second floating body transistors are electrically connected to each other.

8. The integrated circuit according to claim 1, wherein the two source/drain regions and the floating body region form part of an active area segment in that way that the floating body region is separated from a main body of an active area line by a through-hole etched into the active area line, and wherein portions of the back gate electrode are arranged within the through-hole.

9. The integrated circuit according to claim 8, wherein the floating body region is connected to the main body of the active area line by at least two stilts, and wherein the through-hole extends between the at least two stilts.

10. The integrated circuit according to claim 8, wherein the floating body region is completely separated from the main body of the active area line.

11. The integrated circuit according to claim 1, wherein the integrated circuit comprises a memory circuit.

12. The integrated circuit according to claim 1, wherein the integrated circuit comprises a DRAM.

13. A method of manufacturing an integrated circuit with a floating body transistor comprising two source/drain regions, a floating body region arranged between the two source/drain regions, a control gate electrode and a back gate electrode, the method comprising:
forming active area segments on a substrate in that way that the active area segments are surrounded by isolation trenches filled with an insulating material, thereby defining sidewalls between the active area segments and the isolation trenches;
forming trenches adjacent to at least one side of the active area segments, thereby exposing a portion of the sidewalls;
removing material from the active area segments through the exposed portions to etch interspaces to form floating body regions, which are separated from the active area segments by the interspaces;
forming a back gate electrode within the interspaces, the back gate electrode being separated from the floating body region by a first dielectric layer;
forming a third dielectric layer covering the back gate electrode; and
forming a control gate electrode overlying the back gate electrode, the control gate electrode being separated from the floating body region by a second dielectric layer.

14. The method according to claim 13, wherein forming the trenches comprises etching trenches to a first depth, and forming spacers, which cover at least a part of the exposed portion of the sidewalls.

15. The method according to claim 14, further comprising etching the trenches to a second depth after the formation of the spacers.

16. The method according to claim 13, wherein the interspaces separate the floating body regions completely from the substrate.

17. A method of manufacturing an integrated circuit with a floating body transistor comprising two source/drain regions, a floating body region arranged between the two source/drain regions, a control gate electrode and a back gate electrode, comprising:
forming a floating body region in a semiconductor substrate, the floating body region having a top and a bottom surface;
forming a back gate electrode near to the bottom side of the floating body region, the back gate electrode being separated from the floating body region by a first dielectric layer;
forming a third dielectric layer covering the back gate electrode; and
forming a control gate electrode overlying the back gate electrode near to the top side of the floating body region, the control gate electrode being separated from the floating body region by a second dielectric layer.

18. The method according to claim 17, wherein forming the floating body region comprises etching at least one interspace into an active area line to separate the floating body region from a main body of the active area line.

19. A method of operating an integrated circuit having at least one floating body transistor comprising two source/drain regions, a floating body region arranged between the two source/drain regions, a control gate electrode, and a back gate electrode, the method comprising:
applying an electrical signal with a predetermined signal parameter to the floating body transistor capable to modify the potential of the back gate electrode.

20. The method according to claim 19, the method further comprising:
determining a transistor parameter of the floating body transistor; and
determining from the transistor parameter the signal parameter.

21. The method according to claim 20, wherein the transistor parameter comprises a threshold voltage.

22. The method according to claim 20, wherein the steps of determining the transistor parameter, determining the signal parameter and applying the electrical signal are repeated until a predetermined target transistor parameter is determined.
